(19) United States
(12) Patent Application Publication
(10) Pub. No.: US 2023/0195950 A1
(43) Pub. Date: Jun. 22, 2023

(54) COMPUTER-AIDED DESIGN METHOD AND DESIGN SYSTEM

(71) Applicant: Siemens Aktiengesellschaft, München (DE)

(72) Inventors: Stefan Depeweg, Berlin (DE); Behnam Nouri, Berlin (DE); Volkmar Sterzing, Neubiberg (DE)

(21) Appl. No.: 17/926,117

(22) PCT Filed: May 14, 2021
(86) PCT No.: PCT/EP2021/062818

§ 371 Date: Nov. 17, 2022

(30) Foreign Application Priority Data
May 29, 2020 (EP) 20177436.1

(51) Int. Cl. G06F 30/10; G06F 30/27; G06N 3/0455; G06N 3/047

(52) U.S. Cl. CPC G06F 30/10; G06F 30/27; G06N 3/0455; G06N 3/047

(57) ABSTRACT

For a multiplicity of design variants of a technical product, a training structural data set specifying the particular design variant and a training quality value quantifying a predefined design criterion are read in in each case as training data. The training data are taken as a basis for training a Bayesian neural network to determine an associated quality value, together with an associated uncertainty comment, on the basis of a structural data set. Furthermore, a multiplicity of synthetic structural data sets are generated and fed into the trained Bayesian neural network which generates a quality value with an associated uncertainty comment for each of the synthetic structural data sets. The uncertainty comments generated are compared with a predefined reliability comment and one of the synthetic structural data sets is selected on the basis thereof. The selected structural data set is then output for the purpose of producing the technical product.

### CROSS-REFERENCE TO RELATED APPLICATIONS

This application claims priority to PCT Application No. PCT/EP2021/062818, having a filing date of May 14, 2021, which claims priority to EP Application No. 20177436.1 having a filing date of May 29, 2020, the entire contents both of which are hereby incorporated by reference.

### FIELD OF TECHNOLOGY

The following relates to a computer-aided design method and design system.

### BACKGROUND

Computer-aided design or planning instruments are increasingly being used for designing complex technical products, such as e.g., turbine blades, wind turbines, gas turbines, robots, motor vehicles or the components thereof. Such design systems do indeed themselves form a specialized technical field but may generally be used for the design of very different technical products.

Technical products in different technical fields are generally also subject to different technical requirements that are to be predefined as design criteria. Such design criteria may concern for example an efficiency, a tendency toward vibration, a thermal loading, a heat conduction, an aerodynamic efficiency, a performance, a consumption of resources, emissions, material fatigue, securing and/or wear of a respective product or of one of its components. Designing a technical product usually needs to take account of a multiplicity of possibly competing design criteria, the entirety of which should be satisfied as well as possible by the finished product.

Such designs are traditionally carried out by experts who draw up a design proposal, assess the quality thereof and depending thereon, if appropriate, improve the design. Such a procedure is often comparatively complex, however. Moreover, if there is a change in the design criteria, the product to be designed and/or the technical field, many design steps have to be carried out again.

The published patent application WO 2020/007844 A1 discloses using a system of neural networks for designing a turbomachine blade, which networks automatically determine different blade parameters. In that case, however, design variants that are usable to a lesser extent are often generated as well. In particular, there is often uncertainty about the usability of a respective design variant.

### SUMMARY

An aspect relates to a computer-aided design method and design system for generating structure data sets specifying a technical product which enable technical products to be designed more efficiently.

For generating structure data sets specifying a technical product, for a multiplicity of design variants of the technical product, in each case a training structure data set specifying the respective design variant and also a training quality value quantifying a predefined design criterion are read in as training data. Such training data can be taken from a multiplicity of existing databases having design documents for a large quantity of technical products. According to embodiments of the invention, a Bayesian neural network is trained on the basis of the training data, to determine an associated quality value together with an associated uncertainty indication on the basis of a structure data set. Furthermore, a multiplicity of synthetic structure data sets are generated and fed into the trained Bayesian neural network, which generates a quality value with an associated uncertainty indication for each of the synthetic structure data sets. The generated uncertainty indications are compared with a predefined reliability indication, and one of the synthetic structure data sets is selected depending thereon. In this case, such a reliability indication can indicate in particular a maximum permissible uncertainty or inaccuracy of a quality value, a minimum probability of a design criterion being satisfied and/or an interval, a limit value or a quantile for permissible quality values. The selected structure data set is then output for the purpose of producing the technical product.

A design system, a computer program product (non-transitory computer readable storage medium having instructions, which when executed by a processor, perform actions) and also a computer-readable, nonvolatile, storage medium are provided for carrying out the design method according to embodiments of the invention.

The design method according to embodiments of the invention and, also the design system according to embodiments of the invention can respectively be carried out and implemented for example by one or more computers, processors, application-specific integrated circuits (ASICs), digital signal processors (DSPs) and/or so-called “field programmable gate arrays” (FPGAs).

One advantage of embodiments of the invention can be seen in particular in the fact that generally more robust and/or more reliable design variants can be generated owing to uncertainties being explicitly taken into account. In particular, variations of material properties or of production processes can thus be taken into account as well. Moreover, embodiments of the invention are in many cases easily adaptable to different technical fields, provided that a sufficient amount of training data is available for a respective technical field.

Advantageous embodiments and developments of the invention are specified in the dependent claims.

In accordance with one advantageous embodiment of the invention, the synthetic structure data sets can be generated by a trainable generative process, in a randomly induced manner. A multiplicity of efficient methods are available for implementing such a generative process.

In particular, the generative process can be carried out by a variational autoencoder and/or by generative adversarial networks. A variational autoencoder allows in many cases a considerable reduction of dimensions of a parameter space that is crucial for the design, and thus a considerable reduction of a computation complexity required. Generative adversarial networks, often also abbreviated to GANs, allow efficient matching of the generated structure data sets to a design space spanned by the training data.

According to one advantageous embodiment of the invention, the generative process can be trained on the basis of the training structure data sets, to reproduce training structure data sets on the basis of random data fed in. A multiplicity of random data can then be fed into the trained generative process, the synthetic structure data sets being generated by the trained generative process on the basis of the random data. By way of the training, the generative process can as it were learn to generate realistic synthetic structure data sets from random data. It can be observed in many cases that a space of realistic design variants can be exploited comparatively well by synthetic structure data sets generated in this way.

Furthermore, further structure data sets can be fed into the trained generative process. The synthetic structure data sets can then be generated by the trained generative process depending on the further structure data sets fed in. As further structure data sets, in particular training structure data sets and/or already generated structure data sets can be fed into the trained generative process.

In this way, a randomly induced generation of the synthetic structure data sets can be influenced by structures present.

According to one particularly advantageous embodiment of the invention, a multiplicity of data values can be generated and fed into the trained generative process, in which case for a data value respectively fed in, a synthetic structure data set is generated by the trained generative process, and an associated quality value with an associated uncertainty indication is generated by the trained Bayesian neural network on the basis of the synthetic structure data set. Furthermore, in the context of an optimization method an optimized data value can be ascertained in such a way that an uncertainty quantified by the respective uncertainty indication is reduced and/or a design criterion quantified by the respective quality value is optimized. The synthetic structure data set generated for the optimized data value can then be output as selected structure data set. Here and hereinafter, an optimization should also be understood to mean an approximation to an optimum. A multiplicity of standard optimization methods are available for carrying out the optimization, in particular gradient methods, genetic algorithms and/or particle swarm methods. The optimization makes it possible to generate particularly reliable and/or advantageous design variants with regard to the design criterion.

A respective uncertainty indication can be specified by a variance, a standard deviation, a probability distribution, a distribution type and/or a progression indication.

Furthermore, the uncertainty indication generated for the selected structure data set can be output in a manner assigned to the selected structure data set. This allows an estimation about how reliably the design criterion is satisfied. In particular, best-case and worst-case scenarios can be evaluated.

According to a further advantageous embodiment of the invention, a plurality of design criteria can be predefined. The Bayesian neural network can accordingly be trained to determine criterion-specific uncertainty indications for criterion-specific quality values. Furthermore, a plurality of criterion-specific uncertainty indications can be generated for each of the synthetic structure data sets by the trained Bayesian neural network. One of the synthetic structure data sets can then be selected depending on the generated criterion-specific uncertainty indications. Furthermore, different design criteria, criterion-specific quality values and/or criterion-specific uncertainty indications can be weighted by predefined weight factors and a resulting weighted sum can be used for comparison with the reliability indication. Optionally, criterion-specific reliability indications can be provided, too, which can then be compared criterion-specifically with the criterion-specific uncertainty indications.

### BRIEF DESCRIPTION

Some of the embodiments will be described in detail, with reference to the following figures, wherein like designations denote like members, wherein:

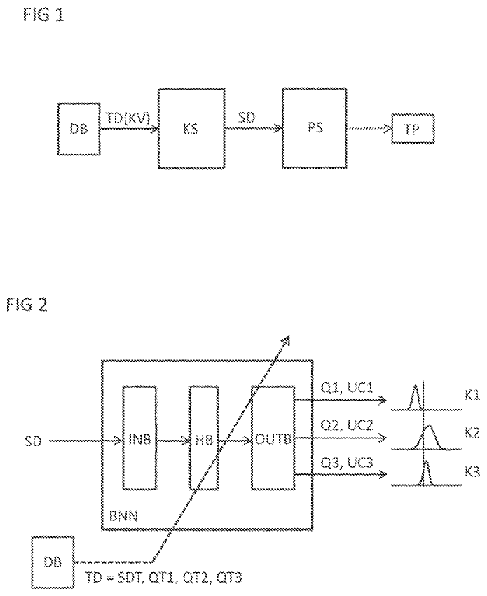

FIG. 1 shows a design system and production system for producing a technical product;

FIG. 2 shows a Bayesian neural network;

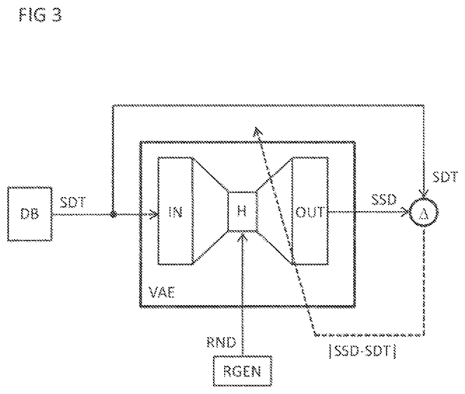

FIG. 3 shows a variational autoencoder in a training phase; and

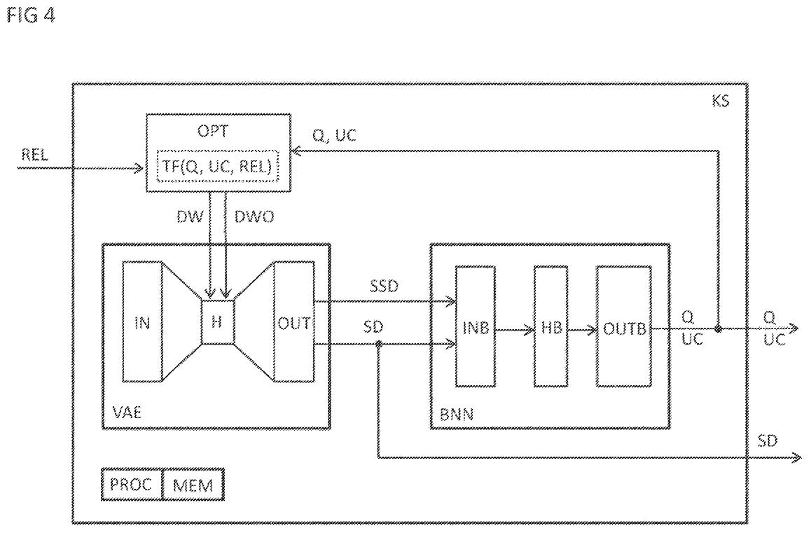

FIG. 4 shows a design system according to embodiments of the invention in an application phase.

### DETAILED DESCRIPTION

FIG. 1 shows a design system KS and a production system PS for producing a technical product TP in a schematic illustration. The production system PS can be for example a manufacturing installation, a robot or a machine tool for product production or product processing on the basis of design data or processing data.

The design data or processing data can be present in particular in the form of structure data sets SD which specify the product TP to be produced or one or more of its components or the physical structure thereof. In this case, the structure data sets SD can indicate e.g., a geometric shape of the technical product TP as a grid model or as a CAD model. Optionally, the structure data sets SD can also comprise indications about a production or processing process of the technical product TP. The technical product TP to be produced can be for example a turbine blade, a wind turbine, a gas turbine, a robot, a motor vehicle or a component of such a technical structure.

The structure data sets SD specifying the technical product TP are generated by the design system KS. The design system KS serves for the computer-aided design of the technical product TP and can for example comprise a computer-aided CAD system or be a part thereof.

According to embodiments of the invention, the design system KS is intended to be enabled to generate realistic and optimized structure data sets SD substantially automatically. For this purpose, the design system KS is trained by machine learning methods, in a training phase, proceeding from a multiplicity of known and available design variants KV of the technical product TP to be produced, to generate new design variants specified by structure data sets SD. In an embodiment, these new design variants should satisfy predefined design criteria better than the known design variants KV. In this case, the design criteria can concern in particular a tendency toward vibration, an efficiency, a stiffness, a thermal loading, a heat conduction, an aerodynamic efficiency, a performance, a consumption of resources, a material consumption, emissions, material fatigue, securing, wear or other physical, chemical or electrical properties of the product TP to be produced or of a component thereof.

For the purpose of training the design system KS, a multiplicity of known design variants KV, as training data TD, are read in from a database DB by the design system KS. Such databases having design data for a large quantity of design variants are available for a multiplicity of products.

In the present exemplary embodiment, the training data TD for a respective design variant KV comprise one or more structure data sets specifying the respective design variant or the physical structure thereof. Furthermore, the training data TD for a respective design variant KV also contain one or more quality values, each quantifying a design criterion or satisfaction of a design criterion for the respective design variant. In this regard, e.g., a first quality value can indicate an aerodynamic efficiency of a design variant of a turbine blade, a second quality value a cooling efficiency, and a third quality value a mechanical loading capacity. In particular, a respective quality value can indicate whether and to what extent a requirement made of the technical product TP and concerning a design criterion is satisfied. The quality values can be derived in particular from available measurement values, empirical values or expert assessments of the known design variants KV.

By virtue of the training—explained in greater detail below—the design system KS is enabled to substantially automatically generate structure data sets SD that are optimized with regard to the design criteria for the production of the technical product TP. In an application phase, the structure data sets SD generated by the trained design system KS are then output to the production system PS, which produces or processes the technical product TP on the basis of the structure data sets SD.

According to embodiments of the invention, the design system KS has a Bayesian neural network BNN, and also a variational autoencoder VAE, both of which are to be trained by machine learning methods in the context of the training of the design system KS.

FIG. 2 shows the Bayesian neural network BNN in a schematic illustration. Insofar as the same or corresponding reference signs are used in FIG. 2 and the other figures, these reference signs denote the same or corresponding entities which can be implemented or configured as described at the relevant point.

The Bayesian neural network BNN forms a so-called statistical estimator. A statistical estimator serves for determining statistical estimated values for objects of a population on the basis of empirical data of a sample of the population. A Bayesian neural network, BNN, can be trained by standard machine learning methods, on the basis of a sample, to estimate one or more estimated values and also the uncertainties thereof with respect to a new object of the population.

In the present exemplary embodiment, the Bayesian neural network BNN comprises an input layer INB for feeding in input data, a hidden layer HB and also an output layer OUTB for outputting output data. Besides the hidden layer HB, the Bayesian neural network BNN can also have one or more further hidden layers.

In the present exemplary embodiment, the Bayesian neural network BNN is trained, by the training data TD fed from the database DB in a training phase, to assess new structure data sets SD in each case with regard to a plurality of predefined design criteria K1, K2 and K3. The assessment takes place by way of a procedure in which, for a respective new structure data set SD, with respect to each design criterion K1, K2 and K3, in each case an uncertainty-exhibiting quality value Q1, Q2 and Q3, respectively, and also the respective uncertainty UC1, UC2 and UC3 thereof are output. In the case of the design of a turbine blade, the design criteria K1, K2 and K3 can concern for example an aerodynamic efficiency, a cooling efficiency and a mechanical loading capacity of the turbine blade and the quality values Q1, Q2 and Q3 can quantify the corresponding design criteria K1, K2 and K3.

For a respective design variant, besides a training structure data set SDT specifying the design variant, the training data TD also contain, for each design criterion K1, K2 and K3 to be assessed, a criterion-specific training quality value QT1, QT2 and QT3, respectively, which quantifies the relevant design criterion K1, K2 and K3, respectively, for the design variant. The training of the Bayesian neural network BNN on the basis of the training data TD is illustrated by a dashed arrow in FIG. 2.

Using the terminology of a statistical estimator, the possible design variants of the technical product TP can be regarded as a population, the training data TD with the multiplicity of known design variants can be regarded as a sample, the design variant specified by the new structure data set can be regarded as a new object, and the uncertainty-exhibiting quality values can be regarded as uncertainty-exhibiting estimated values.

Efficient training methods for such Bayesian neural networks can be gathered for example from the textbook “Pattern Recognition and Machine Learning” by Christopher M. Bishop, Springer 2011.

After the training, the trained Bayesian neural network BNN can be used as a statistical estimator in an application phase. In this case, a respective structure data set SD to be assessed is fed into the input layer INB of the trained Bayesian neural network BNN, which derives therefrom, for each design criterion K1, K2 and K3, a quality value Q1, Q2 and Q3, respectively, quantifying the respective design criterion, and also an uncertainty indication UC1, UC2 and UC3, respectively, quantifying the respective uncertainty of the quality value. The quality values Q1, Q2 and Q3 and also the uncertainty indications UC1, UC2 and UC3 are output by the output layer OUTB.

The uncertainty indications UC1, UC2 and UC3 can be represented in particular by a spread, by an error interval, by an accuracy interval, by a variance, by a standard deviation, by a probability distribution, by a distribution type and/or by a confidence measure. In the case of a probability distribution, different possible quality values can each be assigned a concrete probability value. Alternatively, or additionally, the quality values Q1, Q2 and Q3 determined can each be specified or represented by a mean value or a median of a probability distribution. In this case, a quality value Q1, Q2 and Q3 and the associated uncertainty indications UC1, UC2 and UC3, respectively, can be represented as a value pair, consisting of mean value and variance of a probability distribution.

The design variants specified by the structure data sets SD fed in are evaluated by the trained Bayesian neural network BNN as it were in the light of the training data TD with regard to expected quality and the uncertainty thereof or with regard to the satisfaction of the design criteria K1, K2 and K3.

In the present exemplary embodiment, the structure data sets to be evaluated are generated synthetically by a so-called generative process. In this case, the generative process is implemented by a variational autoencoder VAE.

FIG. 3 illustrates such a variational autoencoder VAE in a training phase. The variational autoencoder VAE comprises an input layer IN, a hidden layer H and also an output layer OUT. Besides the hidden layer H, the variational autoencoder VAE can have further hidden layers. A characteristic of an autoencoder is that the hidden layer H is significantly smaller, i.e., has fewer neurons, than the input layer IN or the output layer OUT.

The variational autoencoder VAE is intended to be trained, on the basis of training structure data sets SDT read in from the database DB, to reproduce the training structure data sets SDT to the greatest possible extent on the basis of random data RND fed in. For this purpose, a large quantity of the training structure data sets SDT are fed as input data into the input layer IN and are processed by the layers IN, H and OUT. The processed data are finally output by the output layer OUT as output data that are intended to serve as synthetic structure data sets SSD in the further course of the method.

The training of the variational autoencoder VAE comprises two aspects, in particular. In accordance with a first aspect, the variational autoencoder VAE is trained such that its output data, here the synthetic structure data sets SSD, reproduce the input data, here the training structure data sets SDT, as well as possible. Insofar as the input data must as it were go through the smaller hidden layer H, and ought to be substantially reconstructable again from the smaller quantity of data present there in accordance with the training aim, a data-reduced representation of the input data is obtained in the hidden layer H. The variational autoencoder VAE thus learns an efficient encoding or compression of the input data.

As a result, a so-called latent parameter space or a latent representation of the training structure data sets SDT and thus as it were a latent design space is realized in the hidden layer H. The data present in the hidden layer H correspond to an abstract description of the design structures contained in the training structure data sets SDT and in many cases are also interpretable geometrically, in particular.

In the further course of the method, the compression of the input data leads to the reduction of the dimensions of the design space to be covered and thus to a considerable reduction of a required computational complexity.

In order to achieve the above training aim, an optimization method is carried out, which sets processing parameters of the variational autoencoder VAE in such a way that a reconstruction error is minimized. In particular, a distance between synthetic structure data sets SSD and the training structure data sets SDT can be determined as the reconstruction error in this case.

In accordance with a second aspect of the training of the variational autoencoder VAE, random data RND are additionally generated by a random data generator RGEN and are fed into the hidden layer H, i.e., into the latent parameter space, whereby the variational autoencoder VAE is excited to generate synthetic structure data sets SSD. In this case, the random data RND can be random numbers, pseudo random numbers, a noise signal and/or other randomly induced data.

Insofar as the variational autoencoder VAE, as described above, is trained to minimize a distance between the synthetic structure data sets SSD generated from the random data RND and the training structure data sets SDT, the variational autoencoder VAE is enabled to generate design variants that are realistic, i.e., as similar as possible to the training structure data sets SDT, in response to randomly based excitation. If the training structure data sets SDT and the synthetic data sets SSD are each represented by data vectors, the distance to be minimized can be determined for example as a mean value, a minimum or some other measure of a respective Euclidean distance between one or a plurality of synthetic structure data sets SSD and a plurality of or all training structure data sets SDT.

For the purpose of training the variational autoencoder VAE or for the purpose of optimizing its processing parameters, the calculated distances are fed back—as indicated by a dashed arrow in FIG. 3—to the variational autoencoder VAE. For the concrete implementation of the training, it is possible to have recourse to a multiplicity of efficient standard methods.

After successful training, the variational autoencoder VAE, just by the feeding of random data RND into the hidden layer H, can be excited to generate substantially realistic synthetic structure data sets SSD.

The use of a variational autoencoder VAE that is excitable by random data is advantageous insofar as new structures not explicitly present in the training structure data sets SDT can also be generated as randomly induced design proposals having similarity with the training structures on account of the training. In this way, the space of realistic and usable design structures can generally be covered well.

The trained variational autoencoder VAE implements a randomly induced generative process for the synthetic structure data sets SSD. Alternatively or additionally, such a generative process can also be implemented by generative adversarial networks.

FIG. 4 illustrates a design system KS according to embodiments of the invention comprising a trained Bayesian neural network BNN and a trained variational autoencoder VAE in an application phase. The respective training of the Bayesian neural network BNN and of the variational autoencoder VAE was carried out as described above.

For reasons of clarity, FIG. 4 explicitly illustrates quality values Q and uncertainty indications UC only for a single design criterion.

The design system KS has one or more processors PROC for carrying out the required method steps, and also one or more memories MEM for storing data to be processed.

The design system KS furthermore has an optimization module OPT for optimizing structure data sets to be generated. In the present exemplary embodiment, the structure data sets are optimized with regard to the resulting quality values Q, the associated uncertainty indications UC and also a reliability indication REL. For this purpose, a target function TF to be optimized is implemented in the optimization module OPT. Depending on the quality value Q and the associated uncertainty indication UC of a design variant and also depending on the reliability indication REL, the target function TF calculates a merit value quantifying a merit, a suitability or some other quality of the design variant. Such a target function is often also referred to as a cost function or reward function.

The reliability indication REL quantifies a reliability with which a respective design criterion is to be satisfied, which reliability is demanded for the technical product TP. The reliability indication REL can indicate in particular a minimum probability with which a respective design criterion is to be satisfied, a maximum acceptable uncertainty or inaccuracy of a quality value and/or a maximum failure probability of the technical product TP.

In order to ascertain the reliability of a design variant, the reliability indication REL is to be compared in particular with uncertainty indications of the quality values of the design variant. Optionally, a plurality of reliability criteria and thus a plurality of criterion-specific reliability indications can be provided. Accordingly, a reliability of a design variant can be ascertained by criterion-specific comparisons between criterion-specific uncertainty indications and associated criterion-specific reliability indications.

The target function TF can be implemented for example such that the merit value to be calculated rises or falls if a desired quality value Q of the technical product TP respectively rises or falls and/or an uncertainty indication UC of the quality value Q respectively falls or rises. Accordingly, the merit value may fall if the uncertainty indication UC does not satisfy a reliability criterion quantified by the reliability indication REL and/or the quality value Q exceeds a limit value quantified by the reliability indication REL. In order to determine an individual merit value, different optimization criteria of the target function TF can be weighted by suitable weighting factors. Such a target function TF can then be maximized by the optimization module OPT by a standard optimization method.

In the present exemplary embodiment, for the technical product TP to be produced, a predefined reliability indication REL is communicated to the optimization module OPT. In the context of the optimization, the optimization module OPT then generates a multiplicity of randomly induced data values DW, e.g., by a random data generator, and feeds them into the hidden layer H of the trained variational autoencoder VAE. The data values excite the trained variational autoencoder VAE to generate synthetic structure data sets SSD which, as already explained above, specify substantially realistic design variants of the technical product TP.

The synthetic structure data sets SSD are fed into the input layer INB of the trained Bayesian neural network BNN as input data. Consequently, by the trained Bayesian neural network BNN, for a respective synthetic structure data set SSD, a quality value Q and also an uncertainty indication UC for the quality value Q are generated and output as output data via the output layer OUTB. In this case, the quality value Q quantifies a design criterion of the design variant specified by the respective synthetic structure data set SSD.

The generated quality values Q and uncertainty indications UC are communicated to the optimization module OPT, which calculates therefrom a merit value for the respective synthetic structure data set SSD by the target function TF. The further generation of the data values DW by the optimization module OPT is then effected in such a way that the merit values respectively resulting therefrom are maximized or optimized in some other way.

The optimization of the data values DW is effected iteratively in the latent parameter space. As already explained above, the optimization can be concretely carried out using a multiplicity of efficient standard optimization methods, such as, for example, gradient methods, particle swarm optimizations and/or genetic algorithms.

In this way, a data value DWO that is optimized in the above regard, i.e., leads to a high merit value, is determined by the optimization module OPT. The optimization module OPT feeds the data value into the hidden layer H of the trained variational autoencoder VAE, which generates an optimized synthetic structure data set SD therefrom. The optimized synthetic structure data set SD is selected as structure data set to be output and is output by the design system KS for the design and production of the technical product TP.

Furthermore, the selected structure data set SD is fed into the input layer INB of the trained Bayesian neural network BNN, which derives therefrom a quality value Q for the selected structure data set SD and also an uncertainty indication UC for the quality value Q. The quality value Q and the uncertainty indication UC for the selected structure data set SD are then output by the design system KS in a manner assigned to the structure data set SD.

The structure data set SD that is output specifies an optimized, new design variant of the product TP to be produced and can be communicated to the production installation PS for the production or processing of the product.

By virtue of the explicit inclusion or minimization of uncertainties, by embodiments of the invention it is possible to generate design variants that are generally more robust than those generated by known methods. In many cases, the generated design variants require fewer manual adaptations and have a higher quality than other design variants generated in a data-driven manner. Furthermore, on the basis of the uncertainty indications, best-case or worst-case scenarios can be evaluated in a simple manner. In particular, risks associated with design specifications not being satisfied can be estimated more easily. Furthermore, material fluctuations or fluctuations in the production process can be taken into account in a natural way in the method according to embodiments of the invention. Insofar as embodiments of the invention essentially only relies on assessed training structure data sets, a design system KS according to embodiments of the invention can generally easily be applied to many technical fields for which a sufficient amount of training data is available.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A computer-implemented design method for generating structure data sets specifying a technical product, wherein
a) for a multiplicity of design variants of the technical product, in each case a training structure data set specifying the respective design variant and also a training quality value quantifying a predefined design criterion are read in as training data;
b) a Bayesian neural network is trained on the basis of the training data, to determine an associated quality value together with an associated uncertainty indication on the basis of a structure data set;
c) a multiplicity of synthetic structure data sets are generated and fed into the trained Bayesian neural network;
d) a quality value with an associated uncertainty indication is generated for each of the synthetic structure data sets by the trained Bayesian neural network;
e) the generated uncertainty indications are compared with a predefined reliability indication and one of the synthetic structure data sets is selected depending thereon; and
f) the selected structure data set is output for the purpose of producing the technical product.

2. The method as claimed in claim 1, wherein the synthetic structure data sets are generated by a trainable generative process.

3. The method as claimed in claim 2, wherein the generative process is carried out by a variational autoencoder and/or by generative adversarial networks.

4. The method as claimed in claim 2, wherein the generative process is trained on the basis of the training structure data sets, to reproduce training structure data sets on the basis of random data fed in,
in that a multiplicity of random data are generated and fed into the trained generative process, and
in that the synthetic structure data sets are generated by the trained generative process on the basis of the fed-in multiplicity of generated random data.

5. The method as claimed in claim 2, wherein further structure data sets are fed into a trained generative process, and in that the synthetic structure data sets are generated by the trained generative process depending on the further structure data sets fed in.

6. The method as claimed in claim 2, wherein the generative process is trained, on the basis of the training structure data sets, to reproduce training structure data sets on the basis of random data fed in,
in that a multiplicity of data values are generated and fed into the trained generative process,
in that for a data value respectively fed in,
a synthetic structure data set is generated by the trained generative process, and
an associated quality value with an associated uncertainty indication is generated by the trained Bayesian neural network on the basis of the synthetic structure data set,
in that in the context of an optimization method an optimized data value is ascertained in such a way that an uncertainty quantified by the respective uncertainty indication is reduced and/or a design criterion quantified by the respective quality value is optimized, and in that the synthetic structure data set generated for the optimized data value is output as selected structure data set.

7. The method as claimed in claim 1, wherein a respective uncertainty indication is specified by a variance, a standard deviation, a probability distribution, a distribution type and/or a progression indication.

8. The method as claimed in claim 1, wherein the uncertainty indication generated for the selected structure data set is output in a manner assigned to the selected structure data set.

9. The method as claimed in claim 1, wherein a plurality of design criteria are predefined, in that the Bayesian neural network is trained to determine criterion-specific uncertainly indications for criterion-specific quality values,
in that a plurality of criterion-specific uncertainty indications are generated for each of the synthetic structure data sets by the trained Bayesian neural network, and
in that one of the synthetic structure data sets is selected depending on the generated criterion-specific uncertainly indications.

10. A design system for generating structure data sets specifying a technical product, configured for carrying out a method as claimed in claim 1.

11. A computer program product, comprising aa computer readable hardware storage device having computer readable program code stored therein, the program code executable by a processor of a computer system to implement a method configured for carrying out a method as claimed in claim 1.

12. A computer-readable storage medium comprising a computer program product as claimed in claim 11.
